(19) United States
(12) Patent Application Publication
(10) Pub. No.: US 2026/0173476 A1
(43) Pub. Date: Jun. 18, 2026

(54) SPLIT-GATE SILICON CARBIDE DEVICE WITH BURIED FIELD LIMITING RING AND PREPARATION METHOD THEREOF

(71) Applicant: Fudan University, Shanghai (CN)

(72) Inventors: Qingqing SUN, Shanghai (CN); Wei ZHANG, Shanghai (CN); Hang XU, Shanghai (CN)

(21) Appl. No.: 18/716,081

(22) PCT Filed: May 15, 2023
(86) PCT No.: PCT/CN2023/094193

§ 371 Date: Jun. 3, 2024

(30) Foreign Application Priority Data
May 10, 2023 (CN) 202310523462.0

(51) Int. Cl. H10D 62/832; H10D 30/01; H10D 64/27

(52) U.S. Cl. CPC H10D 62/8325; H10D 30/0297; H10D 64/513; H10D 64/516

(57) ABSTRACT

The present invention discloses a split-gate silicon carbide device with a buried field limiting ring and a preparation method thereof. The device comprises, from bottom to top, a drain electrode, a drift region and a P-well region, and also comprises a trench, which runs through the P-well region; a buried P-type field limiting ring, which is formed on the periphery of the trench bottom; a P⁺ region and an N⁺ region, which are connected to each other and formed on the P-well region on both sides of the trench; a gate electrode, which is formed in the trench, including a transistor gate located on the outer side and a field limiting ring contact plug located in the middle region, the transistor gate being wrapped in an oxide layer, the top of the field limiting ring contact plug being connected to the source electrode, the bottom of the field limiting ring contact plug being connected to the buried P-type field limiting ring; and a source electrode, which covers the surface of the device, wherein the P-type field limiting ring is connected to the source electrode through the field limiting ring contact plug, achieving equipotential with the source electrode to reduce the electric field in the gate oxide layer on both sides of the trench, so that the device depletion region is limited outside the channel region on both sides of the trench in the reverse bias state.

### FIELD OF THE INVENTION

The present invention relates to the field of semiconductor technology, and in particular, to a split-gate silicon carbide device with a buried field limiting ring and a preparation method thereof.

### BACKGROUND OF THE INVENTION

In Comparison with traditional silicon materials, silicon carbide has three most significant characteristics: large forbidden bandwidth, high critical breakdown field strength, and high thermal conductivity. Specifically, in terms of forbidden bandwidth, the forbidden bandwidth of 4H-type silicon carbide is three times that of silicon, so can work stably at higher temperatures (such as automotive electronics); in terms of critical breakdown field strength, the critical breakdown field strength of silicon carbide can reach 10 times that of silicon, being able to produce high voltage withstand power devices with higher impurity concentration and thinner drift layer thickness, thereby achieving the three characteristics of “high voltage withstand”, “low conduction resistance” and “high frequency” simultaneously. In terms of thermal conductivity, the thermal conductivity of silicon carbide can reach three times that of silicon, being able to improve thermal conductivity, and high thermal conductivity is also conducive to the development of electronic components towards miniaturization. At the same time, the design and processing of a SiC MOS are similar to that of a silicon-based MOS, and its good compatibility makes it a substitute for silicon-based power devices.

SiC MOSFETs also have problems, most of which are directly related to the gate oxide layer. During the reverse bias process, there is a fairly high electric field at the gate oxide layer. In order to utilize the high breakdown ability of silicon carbide, it is necessary to alleviate the electric field at the gate oxide layer, especially for trench-gate type SiC MOSFETs, the concentration of electric field at the bottom of the gate trench often leads to long-term reliability problems.

### SUMMARY OF THE INVENTION

In order to solve the above problems, the present invention discloses a split-gate silicon carbide device with a buried field limiting ring, which comprises from bottom to top a drain electrode, a drift region and a P-well region, and also comprises a trench, which runs through the P-well region; a P-type field limiting ring, which is formed on the periphery of the trench bottom; a P⁺ region and an N⁺ region, which are connected to each other and formed on the P-well region on both sides of the trench; a gate electrode, which is formed in the trench, including a transistor gate located on the outer side and a field limiting ring contact plug located in the middle region, the transistor gate being wrapped in an oxide layer, the top of the field limiting ring contact plug being connected to the source electrode, the bottom of the field limiting ring contact plug being connected to the P-type field limiting ring; and a source electrode, which covers the surface of the device, wherein the P-type field limiting ring is connected to the source electrode via the field limiting ring contact plug, achieving equipotential with the source electrode to reduce the electric field in the gate oxide layer on both sides of the trench, so that the device depletion region is limited outside the channel region on both sides of the trench in the reverse bias state.

In the split-gate silicon carbide device with a buried field limiting ring of the present invention, it is preferable that the depth of the transistor gate is greater than the depth of the P-well region.

The present invention also discloses a method of preparing a split-gate silicon carbide device with a buried field limiting ring, comprising the following steps: forming a P-well region on the upper part of an N-doped SiC substrate, forming an N⁺ drain at the bottom, and using the other region as a drift region; forming a P⁺region on both sides of the upper part of the P-well region, and an N⁺ region adjacent to the P⁺ region; forming a U-shaped trench that runs through the P-well region, with the bottom of the trench located in the drift region, and the sidewall of the trench adjacent to the N⁺ region on both sides; forming a P-shaped field limiting ring by self-aligning on the periphery of the trench bottom; in the trench, forming a transistor gate wrapped in an oxide layer on the outer side and a field limiting ring contact plug in the middle region, and the bottom of the field limiting ring contact plug being connected to the P-type field limiting ring; forming a source electrode on the surface of the device, connecting the source electrode to the top of the field limiting ring contact plug; wherein, the P-type field limiting ring is connected to the source electrode through the field limiting ring contact plug, achieving equipotential with the source electrode to reduce the electric field in the gate oxide layer on both sides of the trench, so that the device depletion region is limited outside the channel region on both sides of the trench in the reverse bias state.

In the method of preparing a split-gate silicon carbide device with a buried field limiting ring of the present invention, it is preferable to self-align to form a split-gate structure by etching the gate material, isolate the transistor gate by the self-aligned oxide layer sidewall, and at the same time, obtain a filling region of the field limiting ring contact plug.

In the method of preparing a split-gate silicon carbide device with a buried field limiting ring of the present invention, it is preferable that the steps of forming a transistor gate wrapped in an oxide layer include: forming an oxide layer at the bottom and sidewall of the trench; depositing a polycrystalline silicon layer to cover the oxide layer and completely fill the trench; depositing an oxide layer to cover the surface of the device, defining a metal filling region by photolithography, etching the oxide layer and the polycrystalline silicon layer to expose the P⁺ region surface and part of the N⁺ region surface on both sides of the trench, and exposing the surface of the oxide layer in the middle region at the bottom of the trench, thereby separating the polycrystalline silicon layer to form a split-gate structure as a transistor gate; depositing the oxide layer and etching it back, forming an isolation sidewall on the sidewall of the transistor gate, thereby coating the transistor gate with the oxide layer.

In the method of preparing a split-gate silicon carbide device with a buried field limiting ring of the present invention, it is preferable that the steps of forming the field limiting ring contact plug and the source electrode include: etching the oxide layer, exposing the P-type field limiting ring in the middle region at the bottom of the trench; forming a metal to completely fill the trench and cover the device surface, using the metal layer filled in the trench as a field limiting ring contact plug, and using the metal layer covering the device surface as a source electrode.

In the method of preparing a split-gate silicon carbide device with a buried field limiting ring of the present invention, it is preferable that the upper surface of the oxide layer at the bottom of the trench is lower than the lower surface of the P-well region.

The present invention sets a buried P-type field limiting ring on the periphery of the trench bottom, and connects it to the source electrode through the field limiting ring contact plug, achieving equipotential between the P-type field limiting ring and the source electrode, thereby limiting the device depletion zone outside the channel region on both sides of the trench in the reverse bias state, thus overcoming the phenomenon of excessive electric field near the gate oxide layer of a traditional trench-type Si CMOS, significantly improving the reliability of the device, and at the same time, notably increasing the cell density of silicon carbide.

### BRIEF DESCRIPTION OF THE DRAWINGS

FIG. 1 is a flowchart of the method for preparing a split-gate silicon carbide device with a buried field limiting ring.

FIGS. 2 to 17 are structural diagrams of the various stages of the method of preparing a split-gate silicon carbide device with a buried field limiting ring.

### DETAILED DESCRIPTION OF THE INVENTION

In order to make the purpose, technical solution, and advantages of the present invention clearer, a lucid and complete description of the technical solution in the embodiments of the present invention is provided below in conjunction with the accompanying drawings. It should be understood that the specific embodiments described here are only used to explain, and not to limit, the present invention. The described embodiments are only a part of the embodiments of the present invention, not all of them. Based on the embodiments in the present invention, all other embodiments obtained by a person skilled in the art without contributing creative labor shall fall within the scope of protection of the present invention.

In the description of the present invention, it should be noted that the orientations or position relations indicated by such terms as “up”, “down”, “vertical”, “horizontal” are based on the orientations or position relations shown in the accompanying drawings, only for the convenience of describing the present invention and simplifying the description, rather than indicating or implying that the device or element referred to must have a specific orientation and be constructed and operated in a specific orientation, and therefore shall not be construed as a limitation of the present invention. Besides, the terms “first” and “second” are only used for the purpose of description and shall not be construed as indicating or implying relative importance.

In addition, many specific details of the present invention, such as the structure, materials, dimensions, processing techniques and technologies of the device, are described below to provide a clearer understanding of the present invention. But, as a person having ordinary skill in the art can understand, the present invention may be implemented without following these specific details. Unless otherwise specified in the following text, various parts of the device may be composed of materials known to a person having ordinary skill in the art, or of materials with similar functions that may be developed in the future.

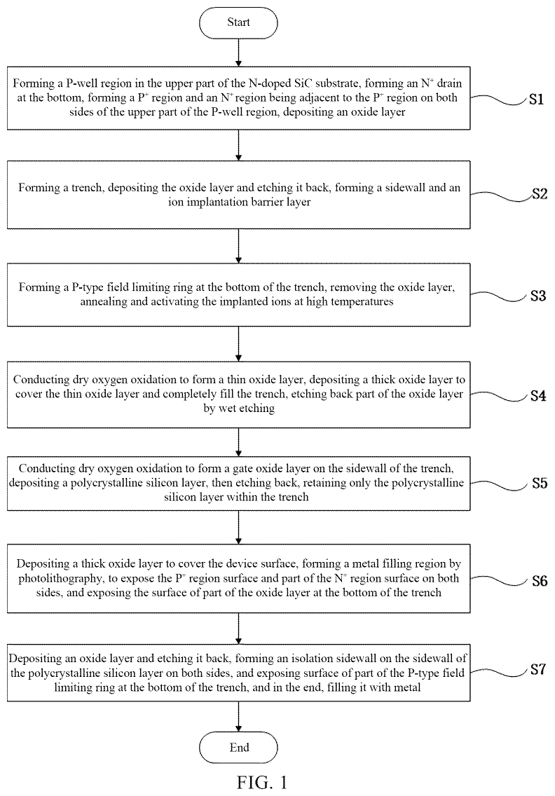

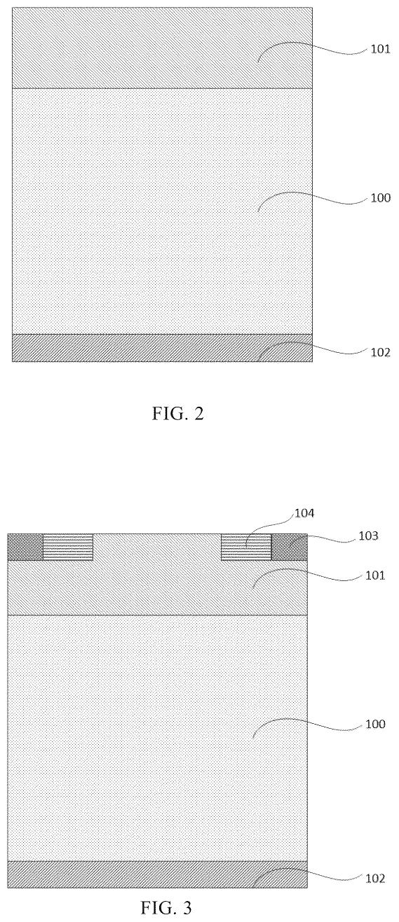

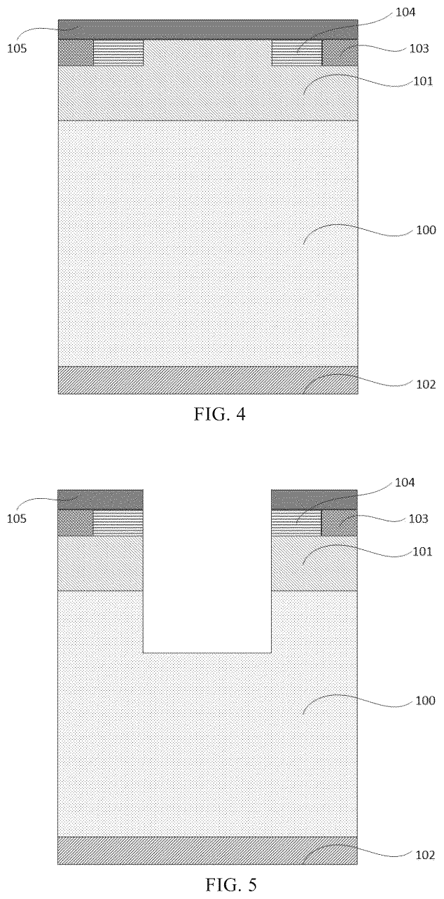

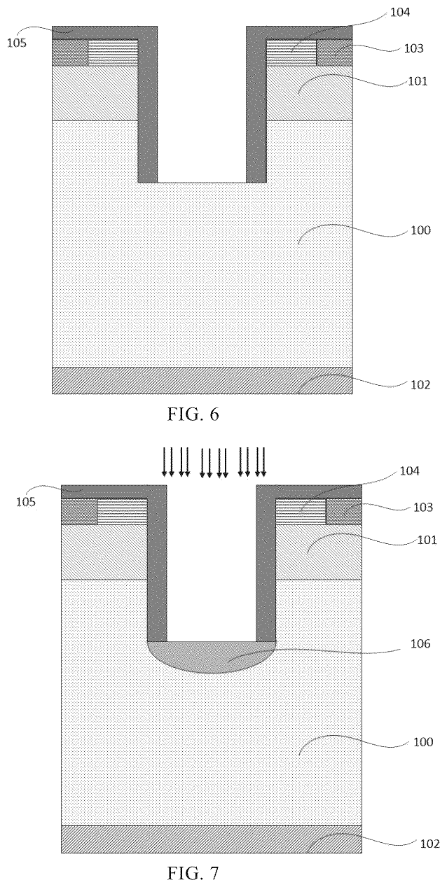

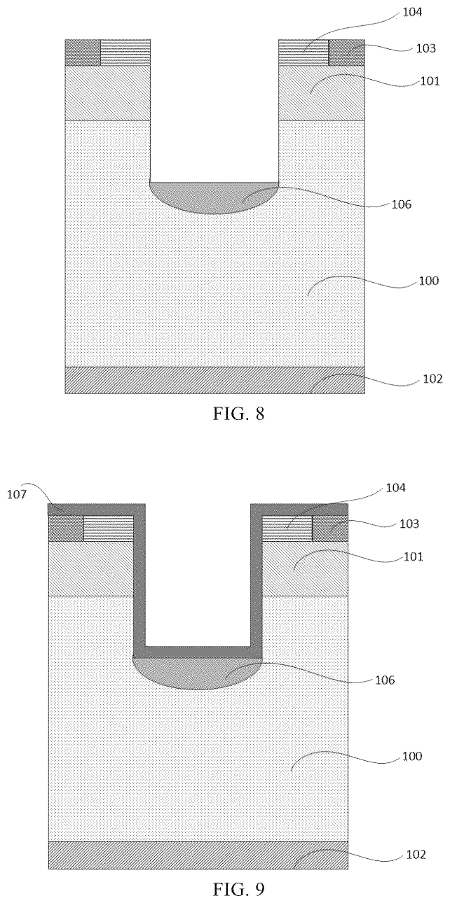

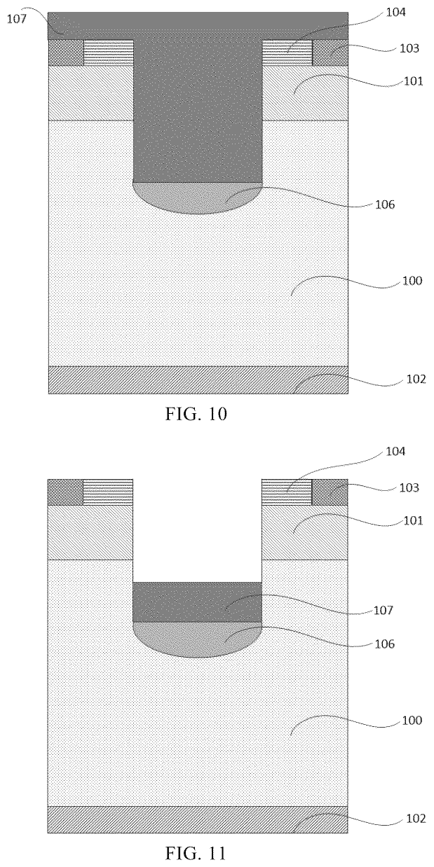

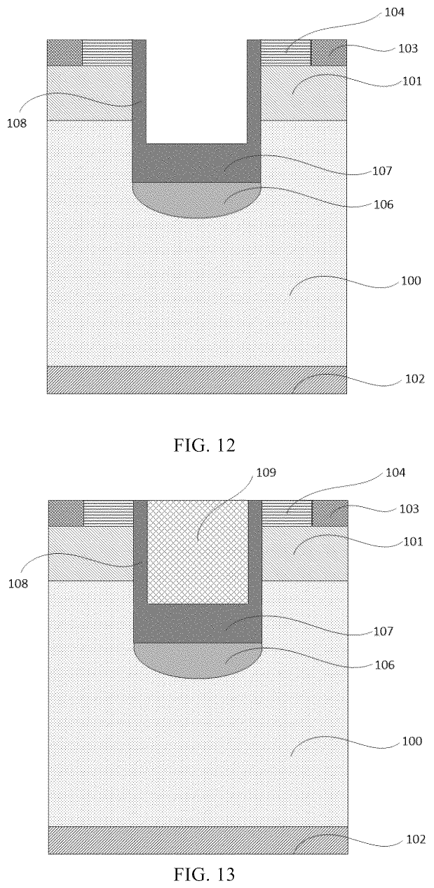

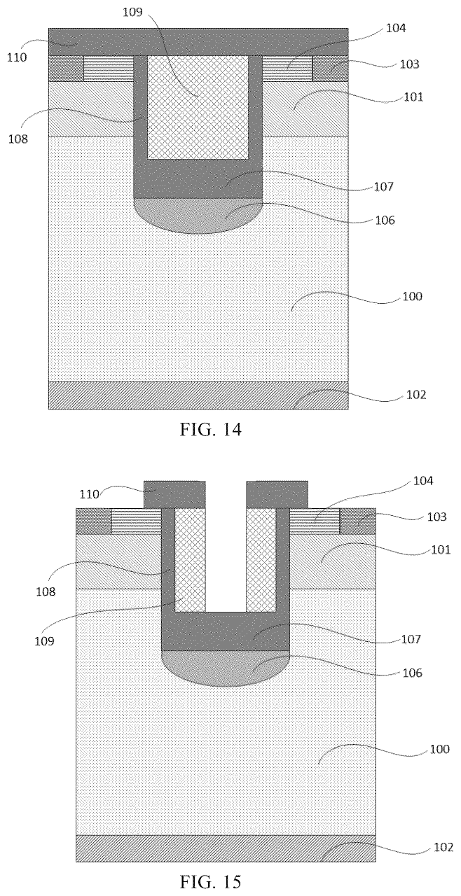

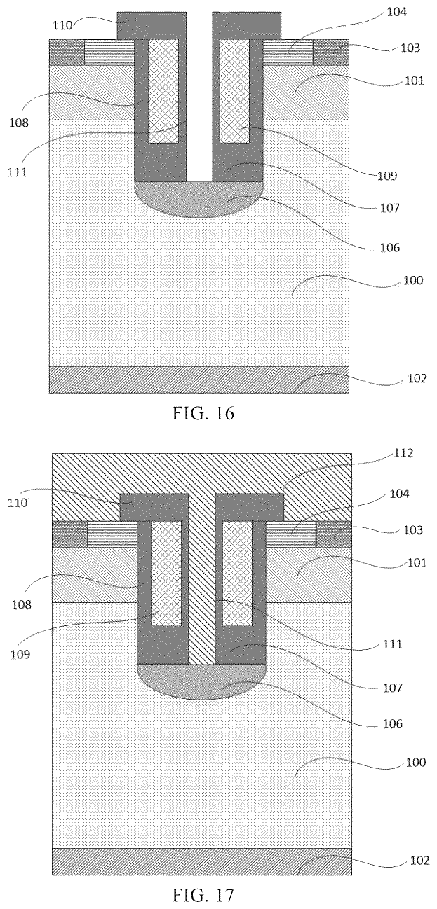

FIG. 1 is a flowchart of the method of preparing a split-gate silicon carbide device with a buried field limiting ring. As shown in FIG. 1, the method of preparing a split-gate silicon carbide device with a buried field limiting ring comprises the following steps:
Step S1: By means of photolithography and ion implantation, forming a P-well region 101 in the upper part of the N⁻ doped epitaxial SiC substrate, and forming an N⁺ drain 102 at the bottom, using the other region as a drift region 100, and the resulting structure is shown in FIG. 2; By means of photolithography and ion implantation, forming a P⁺ region 103 and an N⁺ region 104 adjacent to the P⁺ region on both sides of the upper part of the P-well region 101, respectively, the resulting structure is shown in FIG. 3; thereafter, depositing a first oxide layer 105 with a thickness of 400 nm to cover the device surface, and the resulting structure is shown in FIG. 4.
Step S2: Defining a trench region by photolithography, and etching the first oxide layer 105, P-well region 101, and drift region 100 to form a U-shaped trench; the trench running through the P-well region 101, with the bottom of the trench located in the drift region 100, the sidewall of the trench adjacent to the N⁺ region 104 on both sides, and the resulting structure is shown in FIG. 5; thereafter, depositing the first oxide layer 105 and etching it back, so that the first oxide layer 105 covers the sidewall of the trench and the P⁺ region 103 and N⁺ region 104 on both sides, forming a sidewall and an ion implantation barrier layer, and at the same time, exposing the drift region 100 at the bottom of the trench, the resulting structure is shown in FIG. 6.
Step S3: Performing ion implantation and self-aligning at the bottom of the trench to form a buried P-type field limiting ring 106, the resulting structure is shown in FIG. 7; thereafter, removing all oxide layers, annealing and activating the implanted ions at high temperatures, the resulting structure is shown in FIG. 8.
Step S4: Conducting dry oxygen oxidation to form a thin second oxide layer 107 at the bottom and sidewall of the trench, as well as on the P⁺ region 103 and the N⁺ region 104 located on both sides of the trench, the resulting structure is shown in FIG. 9; thereafter, depositing a second oxide layer 107 with a certain thickness to cover the thin second oxide layer 107 and completely fill the trench, the resulting structure is shown in FIG. 10; in the end, etching back part of the second oxide layer 107 by wet etching, the etching depth exceeding the depth of the P-well region 101 on both sides, with only part of the second oxide layer 107 retained at the bottom of the trench, and the resulting structure is shown in FIG. 11.
Step S5: Conducting dry oxygen oxidation to form a third oxide layer 108 as the gate oxide layer on the sidewall of the trench, the result structure is shown in FIG. 12; depositing a polycrystalline silicon layer 109 to cover the third oxide layer 108 and completely fill the trench, then etching back part of the polycrystalline silicon layer, retaining only the polycrystalline silicon layer 109 within the trench, the resulting structure is shown in FIG. 13.
Step S6: Depositing a fourth oxide layer 110 to cover the device surface, and the resulting structure is shown in FIG. 14; defining a metal filling region by photolithography, etching the fourth oxide layer 110 and the polycrystalline silicon layer 109 to expose the P⁺ region 103 surface and part of the N⁺ region 104 surface on both sides of the trench, and exposing the surface of the second oxide layer 107 in the middle region at the bottom of the trench, thus separating the polycrystalline silicon layer 109 to form a split-gate structure as a transistor gate, the resulting structure is shown in FIG. 15.
Step S7: Depositing an oxide layer and etching it back, forming a fifth oxide layer 111 as an isolation sidewall on the sidewall of the polycrystalline silicon layer 109 on both sides, and exposing the buried P-type field limiting ring 106 in the middle region of the trench bottom, the resulting structure is shown in FIG. 16; in the end, forming a metal layer 112 to completely fill the trench and cover the device surface, the resulting structure is shown in FIG. 17; using the metal layer filled in the trench as the field limiting ring contact plug, and using the metal layer covering the device surface as the source electrode, the P-type field limiting ring 106 achieving equipotential with the source electrode through the field limiting ring contact plug.

As shown in FIG. 17, the split-gate silicon carbide device with a buried field limiting ring comprises, from bottom to top, a drain electrode 102, a drift region 100 and a P-well region 101, and also comprises a trench, which runs through the P-well region 101; a P-type field limiting ring 106, which is formed on the periphery of the trench bottom; a P⁺ region 103 and an N⁺ region 104, which are connected to each other and formed on the P-well region 101 on both sides of the trench; a gate electrode, which is formed in the trench, including a transistor gate 109 located on the outer side and a field limiting ring contact plug located in the middle region, the transistor gate 109 being wrapped with an oxide layer, the top of the field limiting ring contact plug being connected to the source electrode, and the bottom of the field limiting ring contact plug being connected to the P-type field limiting ring 106; and a source electrode, which covers the surface of the device.

By providing a P-type field limiting ring on the periphery of the trench bottom, connecting the P-type field limiting ring to the source electrode through the field limiting ring contact plug, and achieving equipotential with the source electrode, the electric field near the gate oxide layer on both sides of the device under high reverse bias voltage can be significantly reduced, and the reliability of the device improved. In other words, the buried P-type field limiting ring is connected to the source potential through the field limiting ring contact plug, and in the reverse bias state, the depletion region of a device is limited outside the channel region on both sides. At the same time, this structure also achieves the reduction of Miller capacitance, improves the switching speed of the device, and can effectively reduce the switching loss of the device.

The content above is only the specific implementation of the present invention. The scope of protection of the present invention is not limited to this. Any variations or substitutions that can be easily thought of by a person having ordinary skill in the art within the technical scope of disclosure of the present invention shall be covered by the claimed scope of protection of the present invention.

What is claimed is:

1. A split-gate silicon carbide device with a buried field limiting ring, characterized in that comprises, from bottom to top, a drain electrode, a drift region and a P-well region, and further comprises:
a trench, which runs through the P-well region;
a P-type field limiting ring, which is formed on the periphery of the trench bottom;
a P⁺ region and an N⁺ region, which are connected each other and formed on the P-well region on both sides of the trench;
a gate electrode, which is formed in the trench, including a transistor gate located on the outer side and a field limiting ring contact plug located in the middle region, the transistor gate being wrapped with an oxide layer, the top of the field limiting ring contact plug being connected to the source electrode, the bottom of the field limiting ring contact plug being connected to the P-type field limiting ring; and
a source electrode, which covers the surface of the device,
wherein the P-type field limiting ring is connected to the source electrode by the field limiting ring contact plug, achieving equipotential with the source electrode to reduce the electric field in the gate oxide layer on both sides of the trench, so that the device depletion region is limited to the outside of the channel region on both sides of the trench in the reverse bias state.

2. The split-gate silicon carbide device with a buried field limiting ring according to claim 1, characterized in that,
the depth of the transistor gate is greater than the depth of the P-well region.

3. A method of preparing a split-gate silicon carbide device with a buried field limiting ring, characterized in that,
comprises the following steps:
forming a P-well region on the upper part of an N⁻ doped SiC substrate, forming an N⁺ drain at the bottom, and using the other region as a drift region;
forming a P⁺ region and an N⁺ region being adjacent to the P⁺ region on both sides of the upper part of the P-well region;
forming a trench that runs through the P-well region with the bottom of the trench being located in the drift region and the sidewall of the trench being adjacent to the N⁺ region on both sides;
forming a P-shaped field limiting ring by self-aligning on the periphery of the trench bottom;
forming, in the trench, a transistor gate wrapped with an oxide layer on the outer side and a field limiting ring contact plug in the middle region, and the bottom of the field limiting ring contact plug being connected with the P-type field limiting ring;
forming a source electrode on the surface of the device, connecting the source electrode to the top of the field limiting ring contact plug;
wherein, the P-type field limiting ring is connected with the source electrode by the field limiting ring contact plug, achieving equipotential with the source electrode to reduce the electric field in the gate oxide layer on both sides of the trench, so that the device depletion region is limited to the outside of the channel region on both sides of the trench in the reverse bias state.

4. The method of preparing a split-gate silicon carbide device with a buried field limiting ring according to claim 3, characterized in,
self-aligning to form a split-gate structure by etching the gate material,
isolating the transistor gate by the self-aligned oxide layer sidewall, and at the same time, obtaining a filling region of the field limiting ring contact plug.

5. The method of preparing a split-gate silicon carbide device with a buried field limiting ring according to claim 4, characterized in that,
the steps of forming a transistor gate wrapped with an oxide layer include:
forming an oxide layer at the bottom and sidewall of the trench;
depositing a polycrystalline silicon layer to cover the oxide layer and completely fill the trench;
depositing an oxide layer to cover the surface of the device, defining a metal filling region by means of photolithography, etching the oxide layer and the polycrystalline silicon layer to expose the P⁺ region surface and part of the N⁺ region surface on both sides of the trench, and exposing the surface of the oxide layer in the middle region at the bottom of the trench, thereby separating the polycrystalline silicon layer to form a split-gate structure serving as a transistor gate;
depositing the oxide layer and etching it back, forming an isolation sidewall on the sidewall of the transistor gate, thereby wrapping the transistor gate with the oxide layer.

6. The method of preparing a split-gate silicon carbide device with a buried field limiting ring according to claim 5, characterized in that,
the steps of forming the field limiting ring contact plug and the source electrode include:
etching the oxide layer, exposing the P-type field limiting ring in the middle region at the bottom of the trench;
forming a metal to completely fill the trench and cover the device surface, using the metal layer filled in the trench as a field limiting ring contact plug, and using the metal layer covering the device surface as a source electrode.

7. The method of preparing a split-gate silicon carbide device with a buried field limiting ring according to claim 3, characterized in that,
the upper surface of the oxide layer at the bottom of the trench is lower than the lower surface of the P-well region.
